(19) United States
(12) Patent Application Publication
(10) Pub. No.: US 2007/0241352 A1
(43) Pub. Date: Oct. 18, 2007

(54) Group III Nitride Semiconductor Light Emitting Device

(75) Inventors: Takaki Yasuda, Chiba (JP); Akira Bandoh, Chiba (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K. K., Tokyo (JP)

(21) Appl. No.: 11/629,616

(22) PCT Filed: Jun. 16, 2005
(86) PCT No.: PCT/JP05/11488

§ 371 Date: Dec. 15, 2006

Related U.S. Application Data
(60) Provisional application No. 60/584,174, filed on Jul. 1, 2004.

(30) Foreign Application Priority Data
Jun. 18, 2004 (JP) 2004-181561

(51) Int. Cl. H01L 33/00

(52) U.S. Cl. 257/94; 257/E33.001

(57) ABSTRACT

It is an object of the present invention to provide a simple and reliable method for forming a rough structure having inclined side surfaces in a light emitting device, and to provide a group III nitride semiconductor light emitting device that is obtained by the method and is excellent in light extraction efficiency. The inventive group III nitride semiconductor light emitting device comprising group III nitride semiconductor formed on a substrate comprises a first layer of Ge doped group III nitride semiconductor having pits on the surface thereof, and a second layer adjoining on the first layer and having a refractive index different from that of the first layer.

### CROSS REFERENCE TO RELATED APPLICATION

This application is an application filed under 35 U.S.C. §111(a) claiming benefit, pursuant to 35 U.S.C. §119(e)(1), of the filing date of the Provisional Applications No. 60/584,174 filed on Jul. 1, 2004, pursuant to 35 U.S.C. §111(b).

### TECHNICAL FIELD

The present invention relates to a group III nitride semiconductor light emitting device and, more particularly, to a group III nitride semiconductor light emitting device having characteristic layer interface structure that is capable of enhancing the light extraction efficiency.

### BACKGROUND ART

Light emitting devices having a high energy-consumption efficiency (external quantum efficiency) are desirable in view of energy saving. In the case of a GaN type light emitting diode (LED) structure deposited on a sapphire substrate, external quantum efficiency of the LED near the conventional wavelength of 382 nm was, for example, and according to Japanese Patent Application Laid-Open (kokai) No. 2002-164296, 24%. External quantum efficiency can be decomposed into two elements, (internal quantum efficiency)×(light extraction efficiency). Heretofore, however, an improvement in internal quantum efficiency has been mainly attempted only by using a high quality crystal or an optimum structure.

On the other hand, as an example of improving the light extraction efficiency, a method has been adopted, for many years, to increase the light extraction efficiency, in which a LED chip is covered with a resin having an intermediate refractive index between that of the semiconductor and that of air so as to transmit the emitted light efficiently into the resin, and further, the surface of the resin is processed into a curved surface. An increase of light extraction efficiency, by a factor of about 2, can also be achieved, for example, by grinding the substrate in the shape of truncated inverted pyramid, which is available commercially as the X-Bright series by Cree Co. in the USA.

In a LED, generally, as a refractive index of a light emitting layer is generally larger than that of air, light with the angle of incidence larger than the angle of total reflection determined by Snell's law cannot be extracted outside of the light emitting layer. An attempt to change the angle of incidence and to thereby increase light extraction efficiency has already been made, for example by intentionally roughening the surface of the substrate of a light emitting device or by providing an inclined side surface in the shape of inverted pyramid to thereby create rough surface structure. It is, however, most effective to create the effective rough structure at the interface between the light emitting layer and the next layer that has refractive index different from that of the light emitting layer. Or, it is more effective to create effective roughness at the interface in the semiconductor crystal.

On the other hand, in order to obtain a n-type group III nitride semiconductor layer with controlled carrier density, a method of doping with germanium (Ge) has been known (see, for example, Japanese Patent Application Laid-Open (kokai) No. 4-170379). As compared to Si, however, the doping efficiency is low (see, for example, Jpn. J. Appl. Phys., 1992, 31 (9A), 2883), and it has generally been regarded unfavorable for obtaining a n-type group III nitride semiconductor layer. Further, when Ge is doped at high density, pits may be formed on the surface of the n-type group III nitride semiconductor layer and may impair the flatness of the surface, leading to a degraded crystallinity of the semiconductor layer formed thereon (see, for example, Group III Nitride Semiconductor Compounds, CLARENDON Press. (OXFORD), 1998, p. 104.). Therefore, Si, and not Ge, has exclusively been used as n-type doping material.

### DISCLOSURE OF INVENTION

Light extraction efficiency can be improved by constructing a light emitting device having the rough structure with effective inclined side surfaces at the interface between materials of different refractive index formed in a light emitting semiconductor crystal.

It is an object of the present invention to provide a simple and reliable method for forming effective inclined side surface structure in a light emitting crystal, and to provide a group III nitride semiconductor light emitting device that is obtained by the method and is excellent in light extraction efficiency.

The present invention is directed to introducing rough structure having inclined sides at an interface between two layers of different refractive indices in a light emitting device, to thereby permit light, that has been lost by total reflection, to be extracted to the outside and to improve light extraction efficiency of a light emitting device.

Thus, the present invention provides following inventions:

(1) A group III nitride semiconductor light emitting device comprising group III nitride semiconductor formed on a substrate, comprising a first layer of Ge doped group III nitride semiconductor having pits on the surface thereof, and a second layer adjoining on the first layer and having a refractive index different from that of the first layer.

(2) A group III nitride semiconductor light emitting device according to invention 1 above, wherein the atomic concentration of Ge in the first layer is not less than 1×10¹⁶ cm⁻³ and not more than 1×10²² cm⁻³.

(3) A group III nitride semiconductor light emitting device according to invention 1 or 2 above, wherein the second layer is of at least one of materials selected from the group consisting of group III-V compound semiconductors, group II-VI compound semiconductors, and light transmissive or reflective metals, metal oxides, oxides, nitrides, and resins.

(4) A group III nitride semiconductor light emitting device according to any one of inventions 1˜3 above, wherein the first layer is GaN and the second layer is AlₓGa₁₋ₓN (0<x≦1).

(5) A group III nitride semiconductor light emitting device according to any one of inventions 1˜3 above, wherein the first layer is AlₓGa₁₋ₓN (0<x≦1) and the second layer is GaN.

(6) A group III nitride semiconductor light emitting device according to any one of inventions 1˜5 above, wherein the device has a light emitting layer, and the first and the second layers are present on the substrate's side of the light emitting layer.

(7) A group III nitride semiconductor light emitting device according to invention 6 above, wherein the ratio of refractive indices n₁/n₂ of the first layer and the second layer at the wavelength of emitted light is not less than 0.35 and not more than 0.99.

(8) A group III nitride semiconductor light emitting device according to invention 6 or 7 above, wherein the ratio of refractive indices n₂/nₑ of the second layer and the light emitting layer at the wavelength of emitted light is not less than 0.35 and not more than 1.

(9) A group III nitride semiconductor light emitting device according to any one of inventions 1˜8 above, wherein the number density of the pits on the surface of the first layer is not less than 10⁴ cm⁻² and not more than 10¹⁴ cm⁻².

(10) A group III nitride semiconductor light emitting device according to any one of inventions 1˜9 above, wherein the substrate is at least one material selected from the group consisting of sapphire, SiC, GaN, AlN, ZnO, ZrB₂, LiGaO₂, GaAs, GaP and Si.

(11) A lamp that uses a group III nitride semiconductor light emitting device according to any one of inventions 1˜10 above.

With the light emitting device of the present invention, light extracting efficiency can be increased by a factor of up to about 2, so that both light emitting output and electro-optic conversion efficiency can also be increased by a factor of up to about 2. This contributes not only to energy saving but also to suppression of heat generation of the device due to reabsorption of emitted light, and leads to more stable operation and longer useful life of LED.

Also, it is possible to use a simple method in which Ge is doped during the growth of group III nitride semiconductor to reliably introduce roughness having inclined sides at an interface of two layers having different refractive indices.

As used herein, the term “inclined” means that a surface is inclined relative to an average interface (flat surface) between the two layers. Usually, an average interface is a plane parallel to the substrate.

### BRIEF DESCRIPTION OF DRAWINGS

FIG. 1 is a schematic sectional view showing a group III nitride semiconductor light emitting device;

FIG. 2 is a schematic perspective view showing pits in the present invention;

FIG. 3 is a schematic view showing sectional structure of the group III nitride semiconductor light emitting device fabricated in Example 1.

FIG. 4 is a schematic view showing the shape of electrodes in the group III nitride semiconductor light emitting device fabricated in Example 1.

### BEST MODE FOR CARRYING OUT THE INVENTION

The group III nitride semiconductor light emitting device of the present invention is characterized in that it comprises a first layer consisting of group III nitride semiconductor having pits formed on the surface thereof by doping Ge, and a second layer adjoining the first surface and having refractive index different from that of the first layer. The device is preferably formed on a substrate of sapphire (α-Al₂O₃ single crystal) which has relatively high melting point and high thermal resistance, or the like. Optically transparent single crystal materials which transmit light from the light emitting layer are particularly effective as substrates.

As the substrate, any substrate can be used as long as epitaxial growth of group III nitride semiconductor can be carried out. Specifically, cubic or hexagonal silicon carbide (SiC), nitride single crystal material such as AlN, GaN, or the like, oxide single crystal material such as zinc oxide (ZnO), lithium gallium oxide (LiGaO₂), or the like, silicon (Si) single crystal, group III-V compound semiconductor single crystal material such as gallium phosphate (GaP), gallium arsenide (GaAs), or the like, and ZrB₂, or the like, can be used. The substrate is preferably sapphire, SiC, GaN, AlN, or ZnO, and more preferably sapphire, or AlN.

The group III nitride semiconductor layer provided on the substrate is composed from a group III nitride semiconductor represented by the composition formula AlₓGa_{y}In_{z}N₁₋ₐMₐ (0≦X≦1, 0≦Y≦1, 0≦Z≦1, and X+Y+Z=1. M represents a group V element other than N, and a satisfies the following relation: 0≦a<1). When there is mismatching of lattice between the crystal substrate and the group III nitride semiconductor layer formed thereon, it is advantageous to achieve the lamination by interposing a low temperature buffer layer or a high temperature buffer layer to relax the mismatching and to bring about a group III nitride semiconductor layer having excellent crystallinity. The buffer layer may be composed of, for example, aluminum gallium nitride (Al_{X}Ga_{Y}N: 0≦X, Y≦1, and X+Y=1).

A method of growing such a group III nitride semiconductor crystal is not particularly limited, but all the methods known to be useful in growing group III nitride semiconductor, such as MOCVD (Metal Organic Chemical Vapor Deposition), HVPE (Hydride Vapor Phase Epitaxy), MBE (Molecular Beam Epitaxy) methods, may be used. Preferred growth method is MOCVD in view of control of film thickness and mass production. In an MOCVD method, hydrogen (H₂) or nitrogen (N₂) is used as carrier gas, trimethyl gallium (TMGa) or triethyl gallium (TEGa) is used as the source of Ga as group III raw material, trimethyl aluminum (TMAl) or triethyl aluminum (TEAl) is used as the source of Al (group III raw material), trimethyl indium (TMIn) or triethyl indium (TEIn) is used as the source of In (group III raw material), ammonium (NH₃) or hydrazine (N₂H₄) is used as the source of N as group V raw material. Germane gas (GeH₄) or organic germanium compound such as tetramethyl germanium (TMGe) and tetraethyl germanium (TEGe), etc., can be used as the doping source of germanium. In MBE method, elemental germanium can be used as the doping source. As the source for other dopants, monosilane (SiH₄) or disilane (Si₂H₆) is used as the source of Si for n-type dopant, and biscyclopentadienyl magnesium (Cp₂Mg), or bisethylcyclopentadienyl magnesium ((EtCp)₂Mg), for example is used as the source of Mg for p-type dopant.

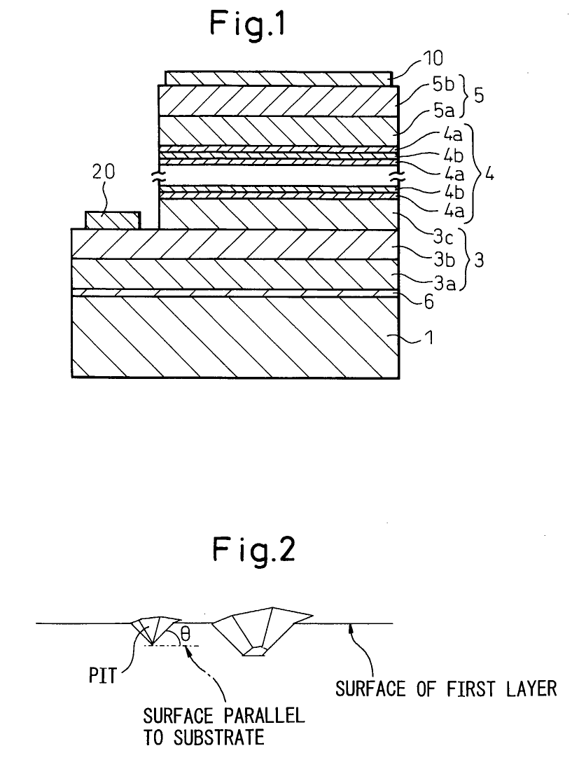

The group III nitride semiconductor light emitting device has a n-type semiconductor layer, a light emitting layer and a p-type semiconductor layer, each layer being formed of group III nitride semiconductor, such that the light emitting layer is sandwiched by the n-type semiconductor layer and the p-type semiconductor layer, and n-type electrode and p-type electrode are provided at predetermined positions. For example, as shown in a schematic sectional view of FIG. 1, a laminate of group III nitride semiconductor formed by laminating, on the substrate (1) formed of sapphire, via a buffer layer (6) of AlN, a n-type semiconductor layer (3) consisting of an underlying layer (3a) of undoped GaN, an n-type contact layer (3b) and an n-type clad layer (3c), a light emitting layer (4) of multiple quantum well structure consisting of alternate lamination of several barrier layers (4a) and well layers (4b) followed by another barrier layer (4a), and a p-type semiconductor layer (5) consisting of a p-type clad layer (5a) and a p-type contact layer (5b), with a p-type electrode (10) on the p-type contact layer (5a) and a n-type electrode (20) on the n-type contact layer (3b), is generally well known.

The first layer and the second layer adjoining thereon can be disposed anywhere in the light emitting device having above-described structure. They may be disposed in the n-type semiconductor layer, or in the p-type semiconductor layer. For example, the first layer may be formed by doping Ge in a portion of the underlying layer (3a) of undoped GaN, and the second layer of undoped AlN may be formed thereon. Alternatively, directly underneath the first barrier layer (4a), a Ge doped group III nitride semiconductor layer having different composition (different refractive index) from the barrier layer may be provided as the first layer, and the first barrier layer (4a) may be used as the second layer. Or, the first layer may be formed by doping Ge to the buffer layer (6) of AlN, and the underlying layer (3a) of GaN may be used as the second layer.

It is also possible that Ge is doped in a portion of the p-type contact layer (5b) to form the first layer, and a group III nitride semiconductor layer of different composition (different refractive index) without doping Ge may be provided as the second layer. In this case, the first layer may be doped with Ge together with a p-type dopant to form a p-type first layer, or may be doped only with Ge.

Also, the topmost portion of the p-type contact layer (5b) may be doped with Ge to form the first layer, and the positive electrode may be used as the second layer. In this case, the positive electrode may be formed in the shape of a lattice, and the insulating protective film and the device sealing resin formed thereon may be used as the second layer. Or, the lattice shaped positive electrode may be directly in contact with air with no layer provided thereon, and air may constitute the second layer.

In the case of the device structure laminated with a p-type semiconductor layer on the substrate's side and a n-type semiconductor layer on the surface side with respect to the light emitting layer, too, the first layer and the second layer may be provided in the same manner as in the above-described structure. For example, a portion of the n-type semiconductor layer on the surface side of the light emitting layer may be doped with Ge to form the first layer having pits formed thereon, and the second layer having different composition (different refractive index) may be formed on it.

In a typical semiconductor light emitting device, refractive index nₑ of the light emitting layer near the wavelength of the emitted light is generally about 1 to 4. Since it is required to extract light into air, light extraction efficiency approaches to 100% when refractive index nₑ of the light emitting layer at the wavelength of the emitted light is closer to refractive index nₒ (=1) of air at the wavelength of the emitted light.

According to Snell's law, a light ray traveling from a medium with refractive index nₑ to a medium with refractive index n₀ cannot enter into the second medium when the angle of incidence α defined such that α=0° for the direction perpendicular to the interface between the two media and α=90° for the direction parallel to the interface, is larger than the angle of total reflection α_{c} defined by sin α_{c}=n₀/nₑ, and light extraction efficiency is decreased accordingly. Thus, as n₀/nₑ approaches 1, α_{c} approaches to 90°, and light extraction efficiency approaches to 100%. In the case of group III nitride semiconductor light emitting device, refractive index of the light emitting layer is typically in the range 2 to 3 and refractive index of external atmosphere (air) to which light is to be extracted is about 1. Thus, difference of refractive index is large, and light extraction efficiency is thereby greatly decreased.

The present invention is directed to improving the light extraction efficiency by forming inclined surfaces. According to the invention, it is possible to extract a light ray with the angle of incidence that does not permit the light to be extracted at a flat interface by forming inclined surfaces to thereby substantially convert the angle of incidence. When the refractive indices of the two media on both sides of the inclined surface are equal, the inclined surface has no optical effect upon the propagation of light. Therefore, it is important that the first layer to which inclined surfaces are to be formed and the second layer provided thereon have different refractive indices at the wavelength of emitted light. It is most effective for improvement of light extraction efficiency to form inclined surfaces at an interface where the ratio of refractive indices between the two layers forming the interface is largest among all the laminating structure from the light emitting layer to the external atmosphere.

Thus, there are two requirements to be fulfilled in order to enhance the effect of the present invention. These requirements will be discussed below. Here, of the first and second layers, the layer disposed closer to the light emitting layer will be referred to in the following as A layer, and the layer disposed farther away from the light emitting layer will be referred to as B layer. Thus, light starts from the light emitting layer, and passes through A layer and B layer in this order to outside. The first requirement is that the refractive index n_{A} of A layer at wavelength of emitted light should be close to the refractive index nₑ of the light emitting layer at wavelength of emitted light. The second requirement is that the refractive index n_{B} of B layer at wavelength of emitted light should not be close to the refractive index n_{A} of A layer at wavelength of emitted light. The second requirement implies that ratio of the refractive index of B layer and refractive index of air should be close to 1, and this requirement is effective in increasing light extraction efficiency from B layer to air up to 100%.

Ratio n_{A}/nₑ of the refractive index nₑ of the light emitting layer and the refractive index n_{A} of A layer at wavelength of emitted light is conveniently not less than 0.35 and not more than 1, preferably not less than 0.7 and not more than 1, and more preferably not less than 0.9 and not more than 1. Ratio n_{B}/n_{A} of the refractive index n_{B} of B layer and the refractive index n_{A} of A layer at wavelength of emitted light is conveniently not less than 0.35 and not more than 0.99, preferably not less than 0.35 and not more than 0.95, and more preferably not less than 0.35 and not more than 0.90.

The refractive index n_{B} of B layer at wavelength of emitted light is conveniently not less than 1.0 and not more than 3.0, preferably not less than 1.0 and not more than 2.5, and more preferably not less than 1.0 and not more than 2.3.

In the present invention, when the laminated structure of the first and second layers is on the substrate's side of the light emitting layer, the first layer is B layer and the second layer is A layer. When the laminated structure is on the side of the light emitting layer opposite to the substrate, the first layer is A layer and the second layer is B layer.

The pits formed on the surface of the first layer are typically in the shape of hexagonal pyramid base on the crystal structure of group III nitride semiconductor. The angle of inclination of the pits in the shape of hexagonal pyramid is basically determined by the inclination angle of the crystal plane of the first layer on which the pits are formed. As shown in FIG. 2, if the inclination angle is defined as the angle of elevation from the plane of the substrate, the inclination angle is about 43.2° for pits formed on {1-102} plane of GaN, and is about 58.4° for pits formed on {11-22} plane of GaN. The inclination angle is about 42.8° for pits formed on {1-102} plane of AlN, and is about 58.0° for pits formed on {11-22} plane of AlN. These angles are further modified by the stress exerted to the first layer. Depending upon the conditions for crystal growth, amorphous pits exhibiting no definite crystal plane may be formed. Pits may be formed with semi circular section, semi-elliptical section, or with a combination of a portion of crystal plane and an amorphous portion. For pits having these shapes, the inclination angle can also be defined by assuming a tangential plane at a point.

In order to increase light extraction efficiency, the inclination angle relative to the substrate plane is conveniently in the range of not less than 5° and not more than 85°, more preferably not less than 15° and not more than 75°, and more preferably not less than 30° and not more than 60°. In the present invention, the inclination angle is measured on sectional SEM photographs of the light emitting device.

Conveniently, the size of pits in the shape of hexagonal pyramid in terms of the length of a side, is, depending on the size of the light emitting device, and in general, in the range of not less than 0.001 μm and not more than 100 μm, preferably not less than 0.1 μm and not more than 10 μm, and more preferably not less than 0.3 μm and not more than 3 μm. If the length of a side is less than 0.001 μm, the pit becomes ineffective in modifying the incident angle of light, and if the length of a side is more than 100 μm, number density of pits becomes too small, which is not preferred.

Conveniently, the depth of pits is in the range of not less than 0.001 μm and not more than 100 μm, preferably not less than 0.1 μm and not more than 10 μm, and more preferably not less than 0.3 μm and not more than 3 μm. If the depth of pit is less than 0.001 μm, the pit becomes ineffective in modifying the incident angle of light, and if the depth of pit is more than 100 μm, the size of pit increases accordingly and number density of pits becomes too small, which is not preferred.

Conveniently, the density of pits present on the surface of the first layer as defined by the ratio of the total area of pits to total surface area of the first layer is in the range not less than 1% and not more than 100%, preferably not less than 10% and not more than 100%, and more preferably not less than 30% and not more than 100%. The larger the area ratio of pits, the pits are more effective in modifying the incident angle of light. The number density of pits is conveniently in the range of not less than 10⁴ cm⁻² and not more than 10¹⁴ cm⁻², preferably not less than 10⁵ cm⁻² and not more than 10¹⁰ cm⁻², and more preferably not less than 10⁶ cm⁻² and not more than 10⁹ cm⁻².

The above-described shape of pits is measured from sectional SEM photographs of the light emitting device, but can be roughly estimated from observation of the surface of the light emitting device in energized state using an optical microscope.

With regard to the layer thickness of the first layer, any thickness is permitted as long as pits of above described depth can be formed. Thus, conveniently, the layer thickness of the first layer is in the range of not less than 0.001 μm and not more than 100 μm, preferably not less than 0.1 μm and not more than 10 μm, and more preferably not less than 0.3 μm and not more than 3 μm.

In the present invention, the pits present on the surface of the first layer are formed by doping Ge into group III nitride semiconductor constituting the first layer. Thus, pits with an intended shape can be formed simply and reliably by adjusting the amount of added Ge during the growth of group III nitride semiconductor.

As factors for controlling the number density and size of the pits, the amount of doped Ge during the growth of the first layer, growth temperature, growth pressure, ratio of group V/group III, etc., can be mentioned. It is quite natural that the amount of doped Ge is a factor, since atomic concentration of Ge in the first layer is directly modified by it. The other conditions mentioned above are also factors because, in the growth conditions for group III nitride semiconductor, there is a range of conditions that is favorable for switching from the growth of a crystal plane parallel to the substrate surface to the growth of a crystal plane inclined to the substrate surface.

The size of pits can also be controlled by the thickness of the first layer, that is, the larger the layer thickness, the larger and the deeper become the pits.

Conveniently, atomic concentration of Ge in the first layer is in the range not less than 1×10¹⁶ cm⁻³ and not more than 1×10²² cm⁻³, preferably not less than 1×10¹⁸ cm⁻³ and not more than 1×10²¹ cm⁻³, and more preferably not less than 1×10¹⁹ cm⁻³ and not more than 1×10²¹ cm⁻³. If atomic concentration of Ge in the first layer is less than 1×10¹⁶ cm⁻³, pits cannot be formed, and if atomic concentration of Ge in the first layer is more than 1×10²² cm⁻³, the crystal integrity of the group III nitride semiconductor such as GaN cannot be maintained. Usually, as atomic concentration of Ge increases, number and size of formed pits also increase.

The concentration of Ge atoms can be measured, for example, by secondary ion mass spectroscopy (SIMS). In this method, a surface of a sample is irradiated with primary ions, and the elements that are thereby ionized and emitted from the surface is subjected to mass spectroscopy. This method permits concentration distribution of a specific element in depth direction to be observed and quantified. This method is also applicable to Ge present in a group III nitride semiconductor layer, and the present invention adopted this method for measurement.

Conveniently, growth temperature of the first layer is in the range not lower than 300° C. and not higher than 1800° C., preferably not lower than 600° C. and not higher than 1500° C., and more preferably not lower than 800° C. and not higher than 1200° C. If growth temperature is lower than 300° C., it is difficult to grow a mother crystal of good quality, and if growth temperature is higher than 1800° C., it is difficult to obtain a sufficient growth rate. In general, pits are more easily formed when the growth temperature is low.

Conveniently, growth pressure for the first layer is in the range of not less than 10⁻¹¹ MPa and not more than 10³ MPa, preferably not less than 10⁻⁴ MPa and not more than 10⁻¹ MPa, and more preferably not less than 10⁻³ MPa and not more than 10⁻¹ MPa. If growth pressure is less than 10⁻¹¹ MPa, it is difficult even with the MBE method to obtain a crystal of good quality, and if growth pressure is more than 10³ MPa, it is difficult even with high pressure bulk crystal growth method to obtain sufficient growth rate. In this pressure range, in general, pits are more easily formed when pressure is high.

Conveniently, the ratio of group V/group III at the time of growth of the first layer is in the range of not less than 1 and not more than 100000, preferably not less than 10 and not more than 10000, and more preferably not less than 100 and not more than 5000. If the ratio is less than 1, group III metal precipitates, and if the ratio is more than 100000, good crystallinity of the first layer cannot be maintained so that it is difficult to form pits of good shape.

The second layer of the present invention may be composed of group III nitride semiconductor of different composition (different refractive index) from the first layer, other group III-V compound semiconductor or group II-VI compound semiconductor. When the first layer is provided on the topmost surface of the p-type semiconductor layer, as mentioned above, the second layer can be composed from light transmissive or light reflective metals (positive electrode), metal oxides (insulating protective film), oxides (insulating protective film) such as SiO₂, nitrides (insulating protective film) such as silicon nitrides, or resins (sealing resins) such as epoxy resins, used as the p-type electrode, insulating protective film or sealing resin formed thereon. Examples of light transmissive or light reflective positive electrode include two layer structure of metals such as Au/Ni or Al/Ti. A large improvement in light extraction efficiency can also be obtained when the second layer is composed from another well-known material for a positive electrode or an insulating film.

When the first layer is provided on the topmost surface of the p-type semiconductor layer, air can be used as the material for composing the second layer without providing a positive electrode, insulating protective film or a sealing resin, and the same large improvement of light extraction efficiency can be obtained.

In selecting the material for composing the second layer, suitable material can be suitably selected such that, by taking account of the refractive indices of the light emitting layer and the first layer at wavelength of emitted light, its refractive index satisfies the above-described preferred range.

The thickness of the second layer is not particularly limited, but a second layer of any thickness may be used. The thickness of the second layer is typically in the range of not less than 0.001 μm and not more than 100 μm, preferably not less than 0.1 μm and not more than 20 μm, and more preferably not less than 0.3 μm and not more than 15 μm. The pits formed on the first layer need not necessarily be filled to obtain a flat surface. However, in view of crystallinity etc. of the semiconductor layer to be grown further thereon, the pits on the first layer are preferably filled to obtain a flat surface.

From the group III nitride semiconductor light emitting device of the present invention, a lamp can be fabricated by, for example, using means well known to those skilled in the art. The group III nitride semiconductor light emitting device of the present invention can be combined with a fluorescent body to fabricate a poly-color LED or a white LED.

### EXAMPLES

The present invention will next be described in detail by way of examples, which should not be construed as limiting the invention thereto.

### Example 1

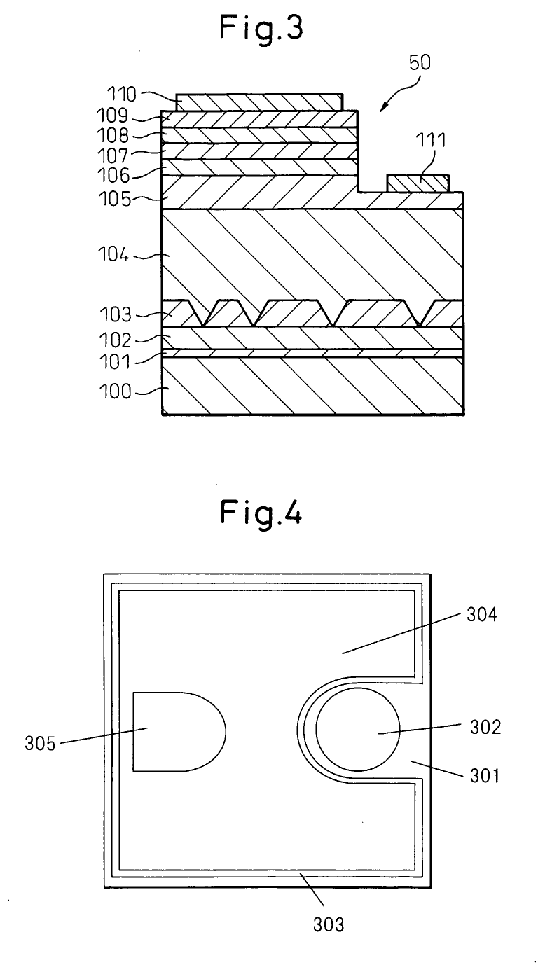

FIG. 3 is a sectional schematic view showing the sectional structure of a group III nitride semiconductor light emitting device 50 fabricated in the present Example. The group III nitride semiconductor layers 101˜109 were formed in the following procedure using a general reduced pressure MOCVD method.

First, a (0001) plane sapphire substrate 100 was placed on a high purity graphite susceptor to be heated to film forming temperature by a high frequency (RF) induction heater. After placing the substrate, nitrogen gas was let flow through the vapor phase growth reaction furnace of stainless steel containing the susceptor to purge the furnace.

After nitrogen gas had been let flow through the vapor phase growth reaction furnace for 8 minutes, the induction heater was started to raise the temperature of the substrate 100 from room temperature to 600° C. in 10 minutes. While the temperature of the substrate 100 was kept at 600° C., hydrogen gas and nitrogen gas flowed through at pressure of 1.5×10⁴ Pa in the vapor phase growth reaction furnace. The furnace was allowed to stay at this temperature and pressure for 2 minutes to perform thermal cleaning on the surface of the substrate 100. After completion of thermal cleaning, the supply of nitrogen gas to the vapor phase growth reaction furnace was stopped. The supply of hydrogen gas was continued.

Thereafter, in hydrogen atmosphere, the temperature of the substrate was raised to 1120° C. After it was confirmed that temperature had been stabilized at 1120° C., hydrogen gas accompanied by a vapor of trimethyl aluminum (TMAl) was supplied to the vapor phase growth reaction furnace for 8 minutes and 30 seconds. Nitrogen (N) produced by decomposition of the nitrogen (N) containing deposition that had been deposited on the inner wall of the vapor phase growth reaction furnace was reacted with the vapor so as to deposit an aluminum nitride (AlN) buffer layer 101 of several nm in thickness on the sapphire substrate. After the supply of hydrogen gas, accompanied by TMAl vapor, to the vapor phase growth reaction furnace was stopped and growth of the AlN buffer layer was completed, the reaction furnace was held in stand-by state for 4 minutes to completely exhaust the TMAl vapor left in the vapor phase growth reaction furnace.

Then, a supply of ammonium (NH₃) gas to the vapor phase growth reaction furnace was started. When 4 minutes had elapsed from the start of NH₃ supply, while the ammonium gas continued to flow, temperature of the susceptor was lowered to 1040° C. After it was confirmed that the temperature of the susceptor had lowered to 1040° C., and after waiting for a while for the temperature to be stabilized, a supply of trimethyl gallium (TMGa) to the vapor phase growth reaction furnace was started. Growth of undoped GaN layer 102 was continued for 20 minutes. The thickness of the undoped GaN layer was 1 μm.

Then, the supply of TMGa was stopped, and the supply of trimethyl aluminum (TMAl) and tetramethyl germanium (hereinafter, (CH₃)₄Ge) was started. Ge doped n-type AlN layer 103 of 1 μm in thickness was formed in 240 minutes. Reduction of surface reflectance was observed by in-situ observation using a surface reflectance measuring instrument mounted on the reaction furnace. This reduction suggests formation of pits and formation of roughness on the surface.

Then, the supply of TMAl and of (CH₃)₄Ge was stopped, and the supply of TMGa was started. In 30 minutes, an undoped GaN layer 104 of 1.5 μm in thickness was formed. In-situ observation of surface reflectance revealed restored surface reflectance, which suggested that the surface was flat again.

Next, while supply of TMGa and NH₃ gas was continued, the wafer temperature was raised to 1120° C., and after the temperature had been stabilized, a supply of monosilane (SiH₄) was started. In 30 minutes, Si doped n-type GaN contact layer 105 of 1.5 μm in thickness was formed.

After a high-Si doped GaN layer 105 was grown, valves for TMGa and SiH₄ were switched so as to stop the supply of these raw materials into the furnace. While ammonium gas continued to flow, the valve was switched and the carrier gas was switched from hydrogen to nitrogen gas. Then, the temperature of the substrate was lowered from 1120° C. to 830° C.

While waiting for change of temperature, the amount of supply of SiH₄ was altered. The amount to be supplied had been studied in advance, and was adjusted such that the electron density of Si doped InGaN clad layer become 1×10¹⁷ cm⁻³. The supply of ammonium gas to the furnace was continued at the same rate. The supply of the carrier gas to bubblers of trimethyl indium (TMIn) and triethyl gallium (TEGa) had been started beforehand. Until the growth of the clad layer was started, SiH₄ gas and vapors of TMIn and TEGa produced by bubbling were circulated together with carrier gas to pipelines of the abatement system, and were discharged through the abatement system.

Then, waiting for the condition in the furnace to be stabilized, valves of TMIn and TEGa and SiH₄ were switched simultaneously to start supply of these raw material into the furnace. The supply was continued for about 10 minutes to form a n-type clad layer 106 of Si doped In_{0.03}Ga_{0.97}N of 10 nm in thickness. Then, the valves of TMIn, TEGa and SiH₄ were switched to stop the supply of these raw material.

Next, a light emitting layer 107 of multiple quantum well structure composed of barrier layers of GaN and well layers of In_{0.06}Ga_{0.94}N was fabricated. In fabricating the multiple quantum well structure, on the n-type clad layer 106 of Si doped In_{0.03}Ga_{0.97}N, a Si doped GaN barrier layer was formed first, and a well layer of In_{0.06}Ga_{0.94}N was formed on the GaN barrier layer. This structure was repeated five times to form a laminate and, on the fifth well layer of In_{0.06}Ga_{0.94}N, a non-doped GaN barrier layer was formed to obtain a structure having multiple quantum well structure sandwiched by GaN barrier layers on both sides.

Thus, after growth of the n-type clad layer had been finished, the supply of TMIn, TEGa and SiH₄ was stopped for 30 seconds, and then, with the temperature of the substrate, pressure in the furnace, flow rate and type of the carrier gas left unaltered, the valves for TEGa and SiH₄ were switched to supply TEGa and SiH₄ to the furnace. After TEGa and SiH₄ were supplied for 7 minutes, the valves were switched again to stop supply of TEGa and SiH₄ to complete growth of Si doped GaN barrier layer, whereby a Si doped GaN barrier layer of 7 nm in thickness was formed.

While the Si doped GaN barrier layer was grown, the flow rate of TMIn into the pipeline of the abatement system was adjusted, in terms of molar flow rate, to twice that at the time of growth of the clad layer.

After growth of the Si doped GaN barrier layer had been finished, supply of group III element raw material was stopped for 30 seconds, and then, with the temperature of the substrate, pressure in the furnace, flow rate and type of the carrier gas left unaltered, valves of TEGa and TMIn were switched to supply TEGa and TMIn to the furnace. After TEGa and TMIn were supplied for 2 minutes, the valves were switched again to stop the supply of TEGa and TMIn and growth of undoped In_{0.06}Ga_{0.94}N well layer was finished, whereby undoped In_{0.06}Ga_{0.94}N well layer of 2 nm in thickness was formed.

After growth of the undoped In_{0.06}Ga_{0.94}N well layer had been finished, supply of group III element raw material was stopped for 30 seconds, and then, with the temperature of the substrate, pressure in the furnace, flow rate and type of the carrier gas left unaltered, supply of TEGa and SiH₄ into the furnace was started, and growth of Si doped GaN barrier layer was performed again.

The above procedure was repeated five times to obtain 5 Si doped GaN barrier layers and 5 undoped In_{0.06}Ga_{0.94}N well layers. Additionally, an undoped GaN barrier layer was formed on the last undoped In_{0.06}Ga_{0.94}N well layer.

On the multiple quantum well structure completed by forming this undoped GaN barrier layer, a p-type clad layer 108 consisting of Mg doped Al_{0.2}Ga_{0.8}N was formed.

After supply of TEGa was stopped and growth of undoped GaN barrier layer was finished, temperature of the substrate was raised to 1100° C. over 2 minutes. Further, the carrier gas was changed to hydrogen. Flow of the carrier gas to bubblers of TMGa, trimethyl aluminum (TMAl), and biscyclopentadienyl magnesium (Cp₂Mg) had been started in advance. Until growth of Mg doped Al_{0.2}Ga_{0.8}N layer was started, vapors of TMGa, TMAl, and Cp₂Mg produced by bubbling were circulated together with the carrier gas to pipelines of the abatement system, and were discharged through the abatement system to the outside.

Waiting for growth conditions in the furnace to be stabilized, valves of TMGa, TMAl and Cp₂Mg were switched to start supply of these raw materials into the furnace. The amount of Cp₂Mg to be let flow had been studied in advance, and was adjusted such that positive hole density in the p-type clad layer 108 consisting of Mg doped Al_{0.2}Ga_{0.8}N become 5×10¹⁷ cm⁻³. After growth was performed over 2 minutes, supply of TMGa, TMAl and Cp₂Mg was stopped and growth of Mg doped Al_{0.2}Ga_{0.8}N layer was terminated, whereby a Mg doped Al_{0.2}Ga_{0.8}N layer 108 of 0.15 μm in thickness was formed.

On the p-type clad layer 108 consisting of Mg doped Al_{0.2}Ga_{0.8}N, a p-type contact layer 109 consisting of Mg doped GaN was formed.

After supply of TMGa, TMAl and Cp₂Mg was stopped and growth of Mg doped Al_{0.2}Ga_{0.8}N clad layer was terminated, supply of group III element raw material and a dopant was stopped for 30 seconds, and then, the amount of Cp₂Mg circulated was changed such that positive hole density of the p-type GaN contact layer become 8×10¹⁷ cm⁻³. With the temperature of the substrate, pressure in the furnace, flow rate and type of the carrier gas left unaltered, supply of TMGa and Cp₂Mg into the furnace was started, and growth of Mg doped p-type GaN contact layer 109 was performed. Then, after growth was performed for 2 minutes and 30 seconds, supply of TMGa and Cp₂Mg was stopped, and growth of Mg doped p-type GaN contact layer was terminated, whereby a Mg doped p-type GaN contact layer 109 of 0.15 μm in thickness was formed.

After growth of Mg doped p-type GaN layer had been finished, current flow to the induction heater was stopped and temperature of the substrate was lowered to room temperature over 20 minutes. While temperature was being lowered from the growth temperature to 300° C., the carrier gas in the furnace was composed only of nitrogen, and 1%, in capacity, of NH₃ was circulated. Then, when it was confirmed that temperature of the substrate had been lowered to 300° C., circulation of NH₃ was stopped, and nitrogen was left as the only atmosphere gas. After it was confirmed that temperature of the substrate had been lowered to room temperature, the wafer was taken out in the atmosphere.

An epitaxial wafer having epitaxial layer structure for semiconductor light emitting device was fabricated following the above-described procedure. Here, at least the topmost Mg doped GaN layer exhibited p-type without annealing process for activating p-type carriers.

Refractive index of the first layer in the present Example was about 2.0, and refractive index of the second layer was about 2.4. Refractive index of the light emitting layer was about 2.4.

Next, using the epitaxial wafer having epitaxial layer structure laminated on sapphire substrate as described above, a light emitting diode 50 as a kind of semiconductor light emitting device was fabricated in following procedures. FIG. 4 is a schematic view showing the shape of electrodes in the light emitting diode 50 fabricated in this Example. On the fabricated wafer, a mask for dry etching was formed by a known photolithographic technology, and then, dry etching of the wafer surface was performed. The dry etching was performed by reactive ion etching method using halogen based gas, and a portion 301 of high-Si doped GaN contact layer 105 was exposed for forming a n-type electrode. On the portion of exposed surface of n-type GaN contact layer, n-type electrode 302 of Ti (1000 Å)/Au (2000 Å) was fabricated. On the surface of the portion 303 of the Mg doped p-type GaN contact layer 109 not subjected to the dry etching, a p-type electrode was fabricated by forming a p-type electrode bonding pad 305 having the structure of titanium, aluminum and gold laminated in this order from the surface and a light transmissive p-type electrode 304 of Au (75 Å)/Ni (50 Å) joined thereto.

The wafer having the p-type electrode and n-type electrode formed in this manner was ground from the rear side of the sapphire substrate until the thickness of the substrate becomes 100 μm, and was further polished to obtain mirror-like surface. Then, the wafer was cut into chips of 350 μm square, and was placed on a submount so that the electrodes become at the bottom. The submount was mounted in a cup of a lead frame, and the submount was connected to the lead frame via wiring to form a light emitting device. Then, the device was sealed with silicone resin in the shape of hemisphere to fabricate a shell-like LED.

When a forward current was passed between the p-type electrode and n-type electrode of the light emitting diode fabricated in this manner, at current of 20 mA, the wavelength of emitted light was 380 nm, optical power output measured with an integrating sphere was 20 mW, and the forward voltage was 3.2 V.

When the current was applied to the LED chip before resin sealing, observation of the chip surface with an optical microscope revealed uniformly bright region and bright spots in the shape of hexagons about 1 μm in size brighter than this region, suggesting that light emitted from the light emitting layer in all directions can be efficiently extracted. The bright spot corresponds to the portion where a pit in the shape of hexagonal pyramid was formed, and the orientation of the hexagon suggested that the pit was composed of the six {11-22} crystal plane of AlN. The number density of the bright spots, or pits, was 1.4×10⁷ cm⁻², and the size of bright spots (pits) was 0.4˜1 μm.

Ge atomic concentration of the Ge doped AlN layer was 4×10¹⁹ cm⁻³. From observation of sectional SEM images, the inclination angle of the pits formed on the first layer was determined to be about 60°. The depth of the pits measured from the SEM image was in the range of 0.6 μm˜1 μm.

### Comparative Example 1

A LED was fabricated in the same manner as in Example 1 above, except that the n-type AlN layer 103 doped with Ge to form pits was not formed. The LED obtained was evaluated as in Example 1. It was found that, with forward current of 20 mA, wavelength of emitted light was 380 nm, optical power output measured by using an integrating sphere was 12 mW, and the forward voltage was 3.2 V.

The bright spots in the shape of hexagon that had been observed in Example 1 was not observed. It was determined that the Ge doped layer 103 having pits formed thereon had been responsible to improvement of light extraction efficiency in Example 1.

### Example 2

Example 2 is an example where AlN layer was formed on the sapphire substrate, and Ge doping was started midway to form the first layer.

As in Example 1, a (0001) plane sapphire substrate 100 was placed on the susceptor in MOCVD furnace. After placing the substrate in the furnace, nitrogen gas was let flow through the furnace for purging.

After nitrogen gas was circulated through the vapor phase growth reaction furnace for 8 minutes, the temperature of the substrate 100 was raised from room temperature to 600° C. in 10 minutes. Then, the substrate 100 was allowed to stand still for 2 minutes for thermal cleaning of the surface of the substrate 100.

Then, temperature of the substrate 100 was raised to 1120° C., and hydrogen gas accompanied by vapor of trimethyl aluminum (TMAL) was supplied for 8 minutes and 30 seconds into the vapor phase growth reaction furnace. Then, supply of TMAl was stopped, and then NH₃ was circulated and an aluminum nitride (AlN) buffer layer 101 of 40 nm in thickness was formed on the sapphire substrate 100.

Then, while ammonium gas continued to be supplied, temperature of the susceptor was lowered to 1040° C. After it was confirmed that temperature of the susceptor had been lowered to 1040° C., supply of TMAl was started, and an undoped AlN layer 102 was grown for 60 minutes. Thickness of the formed undoped AlN layer was 0.25 μm.

Then, while supply of TMAl and NH₃ was left unaltered, supply of (CH₃)₄Ge was started. In 240 minutes, a Ge doped n-type AlN layer 103 of 1 μm in thickness was formed. In-situ observation of the surface reflectance as in Example 1 revealed reduction of reflectance, suggesting formation of pits.

Then, supply of TMAl and (CH₃)₄Ge was stopped, and supply of TMGa was started. In 30 minutes, an undoped GaN layer 104 of 1.5 μm in thickness was formed. In-situ observation of surface reflectance revealed restored surface reflectance, which suggested that the surface was flat again.

Then, the Si doped n-type GaN contact layer 105 and subsequent layers were formed as in Example 1. Further, a shell shaped light emitting diode was fabricated in the same manner as in Example 1.

Refractive indices of the first layer, the second layer and the light emitting layer were about 2.0, about 2.4 and about 2.4, respectively, as in Example 1.

The obtained light emitting diode was evaluated in the same manner as in Example 1. It was found that, with applied current of 20 mA, the wavelength of emitted light was 380 nm, the optical power output measured using an integrating sphere was 22 mW, and the forward voltage was 3.2 V. The number density of the bright spots was 1.4×10⁷ cm⁻², and the size of the bright spots was 0.4 μm˜1 μm. Ge atomic concentration of the Ge doped AlN layer was 4×10¹⁹ cm⁻³, same as in Example 1. The inclination angle of pits formed in the first layer as observed from sectional SEM images was also 60°, same as in Example 1. The depth of pits as measured from sectional SEM images was 0.6 μm˜1 μm.

### Example 3

Example 3 is an example in which an AlN buffer layer 101 and a GaN layer 102 were successively formed, and then the first layer 103 was formed as a Ge doped GaN layer.

As in Example 1, a (0001) plane sapphire substrate 100 was placed on the susceptor in MOCVD furnace. After placing the substrate in the furnace, nitrogen gas was let flow through the furnace for purging.

After nitrogen gas was circulated through the vapor phase growth reaction furnace for 8 minutes, temperature of the substrate 100 was raised from room temperature to 600° C. in 10 minutes. Then, the substrate 100 was allowed to stand still for 2 minutes for thermal cleaning of the surface of the substrate 100.

Then, temperature of the substrate 100 was raised to 1150° C., and hydrogen gas accompanied by vapor of trimethyl aluminum (TMAL) was supplied for 8 minutes and 30 seconds into the vapor phase growth reaction furnace. Then, the supply of TMAl was stopped, and then NH₃ was supplied and an aluminum nitride (AlN) buffer layer 101 of 40 nm in thickness was formed on the sapphire substrate 100.

Then, while ammonium gas was supplied, and temperature of the susceptor was maintained at 1150° C., supply of TMGa was started, and an undoped GaN layer 102 was grown for 40 minutes. Thickness of the formed undoped GaN layer 102 was 2 μm.

Then, while supply of TMGa and NH₃ was left unaltered, a supply of (CH₃)₄Ge was started. In 20 minutes, a Ge doped n-type GaN layer 103 of 1 μm in thickness was formed. In-situ observation of the surface reflectance revealed reduction of reflectance, suggesting formation of pits.

Then, supply of TMGa and (CH₃)₄Ge was stopped, and supply of TMAl was started. In 120 minutes, an undoped AlN layer 104 of 0.5 μm in thickness was formed. In-situ observation of surface reflectance revealed somewhat restored surface reflectance, and this suggested that, although incomplete, the surface was flat again.

Then, the Si doped n-type GaN contact layer 105 and subsequent layers were formed as in Example 1. Further, a shell shaped light emitting diode was fabricated in the same manner as in Example 1.

Refractive indices of the first layer in the present Example was about 2.4, and refractive index of the second layer was about 0.2. Refractive index of the light emitting layer was about 2.4.

The obtained light emitting diode was evaluated in the same manner as in Example 1. It was found that, with applied current of 20 mA, the wavelength of emitted light was 380 nm, the optical power output measured using an integrating sphere was 19 mW, and the forward voltage was 3.2 V. The number density of the bright spots was 1.4×10⁷ cm⁻², and the size of the bright spots was 0.4 μm˜1 μm. Ge atomic concentration of the Ge doped GaN layer was 4×10¹⁹ cm⁻³, and the inclination angle of pits formed in the first layer as observed from sectional SEM images was about 60°. The depth of pits as measured from sectional SEM images was 0.6 μm˜1 μm.

### Example 4

Example 4 is an example in which the first layer was formed as a Ge doped GaN layer on a p-type GaN contact layer.

As in Comparative example 1, an epitaxial wafer for LED having up to p-type GaN contact layer formed was fabricated. Then, as the p-type electrode, on the surface of the Mg doped p-type GaN contact layer, a lattice shaped electrode of 3 layer structure of Rh/Ir/Pt (Pt was on the side of semiconductor) was formed, and p-type electrode bonding pad having lamination structure of titanium, aluminum and gold was formed thereon. The lattice shaped electrode was constructed with electrode width of 2 μm and opening width of 5 μm, ratio of area of openings/area of electrode excluding the portion of bonding pad being 25/49.

Thus, the p-type electrode was first formed in this manner, and the wafer having a portion of the p-type GaN layer exposed was again charged into MOCVD growth apparatus, and using TMGa, NH₃, and TEGe as raw materials and N₂ as carrier gas, a Ge doped GaN layer of 1 μm in thickness was formed on the portion where p-type GaN was exposed, at growth temperature of 500° C. When the surface after the regrowth was observed, it was found that a portion of the p-type lattice shaped electrode was covered by the Ge doped GaN. It was also found that, on the Ge doped GaN layer formed in the 5 μm square opening, 12 pits in average were formed and the pit was in the shape of hexagon of 1 μm on each side. It was found from observation of sectional SEM images that the depth of the pit was 0.6 μm˜1 μm, and the inclination angle was about 60°

This wafer was used to fabricate a shell shaped LED. When this LED was evaluated as in Example 1, it was found that, with applied current of 20 mA, the wavelength of emitted light was 382 nm, optical power output measured using an integrating sphere was 16 mW, and forward voltage was 3.4 V.

In fabricating the shell shaped LED, epoxy resin was used as the sealing resin, so that refractive indices of the first layer, second layer and light emitting layer of the present Example was 2.4, 1.5, and 2.4, respectively.

### INDUSTRIAL APPLICABILITY

The group III nitride semiconductor light emitting device of the present invention has improved light extraction efficiency and high optical power output, and therefore, has very large industrial applicability.

1. A group III nitride semiconductor light emitting device comprising group III nitride semiconductor formed on a substrate, comprising a first layer of Ge doped group III nitride semiconductor having pits on the surface thereof, and a second layer adjoining on the first layer and having a refractive index different from that of the first layer.

2. A group III nitride semiconductor light emitting device according to claim 1, wherein the atomic concentration of Ge in the first layer is not less than 1×10¹⁶ cm⁻³ and not more than 1×10²² cm⁻³.

3. A group III nitride semiconductor light emitting device according to claim 1, wherein the second layer is of at least one of materials selected from the group consisting of group III-V compound semiconductors, group II-VI compound semiconductors, and light transmissive or reflective metals, metal oxides, oxides, nitrides, and resins.

4. A group III nitride semiconductor light emitting device according to claim 1, wherein the first layer is GaN and the second layer is AlₓGa₁₋ₓN (0<x≦1).

5. A group III nitride semiconductor light emitting device according to claim 1, wherein the first layer is AlₓGa₁₋ₓN (0<x≦1) and the second layer is GaN.

6. A group III nitride semiconductor light emitting device according to claim 1, wherein the device has a light emitting layer, and the first and the second layers are present on the substrate's side of the light emitting layer.

7. A group III nitride semiconductor light emitting device according to claim 6, wherein the ratio of refractive indices n₁/n₂ of the first layer and the second layer at the wavelength of emitted light is not less than 0.35 and not more than 0.99.

8. A group III nitride semiconductor light emitting device according to claim 6, wherein the ratio of refractive indices n₂/nₑ of the second layer and the light emitting layer at the wavelength of emitted light is not less than 0.35 and not more than 1.

9. A group III nitride semiconductor light emitting device according to claim 1, wherein the number density of the pits on the surface of the first layer is not less than 10⁴ cm⁻² and not more than 10¹⁴ cm⁻².

10. A group III nitride semiconductor light emitting device according to claim 1, wherein the substrate is at least one material selected from the group consisting of sapphire, SiC, GaN, AlN, ZnO, ZrB₂, LiGaO₂, GaAs, GaP and Si.

11. A lamp that uses a group III nitride semiconductor light emitting device according to claim 1.
